(19) United States
(12) Patent Application Publication
(10) Pub. No.: US 2020/0294977 A1
(43) Pub. Date: Sep. 17, 2020

(54) DISPLAY APPARATUS

(71) Applicant: Qisda Corporation, Taoyuan City (TW)

(72) Inventors: Yi-Cheng KUO, Taoyuan County (TW); Meng-Wei LIN, Taoyuan City (TW); Chih-Chieh SU, Hsinchu County (TW)

(73) Assignee: Qisda Corporation, Taoyuan City (TW)

(21) Appl. No.: 16/817,655

(22) Filed: Mar. 13, 2020

(30) Foreign Application Priority Data
Mar. 15, 2019 (TW) 108108771

(51) Int. Cl. H01L 25/075; H01L 33/58; H01L 33/62

(52) U.S. Cl. CPC H01L 25/0753; H01L 33/58; H01L 2933/0066; H01L 2933/0058; H01L 33/62

(57) ABSTRACT

A display apparatus includes a transparent substrate, light emitting units, and an opaque film. The transparent substrate includes a first transparent surface and a second transparent surface opposing to the first transparent surface. The light emitting units are disposed over the first transparent surface. The opaque film covers on at least one of the first transparent surface and the second transparent surface.

This application claims the benefit of Taiwan application Serial No. 108108771, filed Mar. 15, 2019, the subject matter of which is incorporated herein by reference.

### BACKGROUND OF THE INVENTION

### Field of the Invention

The invention relates in general to a display apparatus.

### Description of the Related Art

For a current light emitting diode (LED) display apparatus applied with jointing technique, a substrate of a display device unit usually uses a transparent glass, and a plurality of the display device units are jointed as a module. The transparent glass used as the substrate has advantages of having excellent flatness and structural support properties, and can provide a stable platform for electronic elements such as a light emitting diode and so on to be disposed thereon under a tendency of thinning a substrate for a display apparatus. However, the transparent glass substrate would allow a user to observe all electronic elements other than a light emitting diode disposed on the transparent glass substrate, which results in a worse visual impression to a user.

### SUMMARY OF THE INVENTION

The invention is directed to a display apparatus having a better display effect.

According to a respect of the present invention, a display apparatus is provided. The display apparatus comprises a transparent substrate, light emitting units, and an opaque film. The transparent substrate comprises a first transparent surface and a second transparent surface opposing to each other. The light emitting units are disposed over the first transparent surface. The opaque film covers on at least one of the first transparent surface and the second transparent surface.

The above and other aspects of the invention will become better understood with regard to the following detailed description of the preferred but non-limiting embodiment (s). The following description is made with reference to the accompanying drawings.

### BRIEF DESCRIPTION OF THE DRAWINGS

FIG. 1 to FIG. 3 illustrate a method for manufacturing a display apparatus according to an embodiment.

FIG. 4 illustrates a substrate structure used for a display device according to another embodiment.

FIG. 5 illustrates a substrate structure used for a display device according to yet another embodiment.

### DETAILED DESCRIPTION OF THE INVENTION

Detailed descriptions of the invention are disclosed below with a number of embodiments. However, the disclosed embodiments are for explanatory and exemplary purposes only, not for limiting the scope of protection of the invention. Besides, secondary elements are omitted in the drawings of the embodiments, so that technical features of the present invention can be more clearly illustrated.

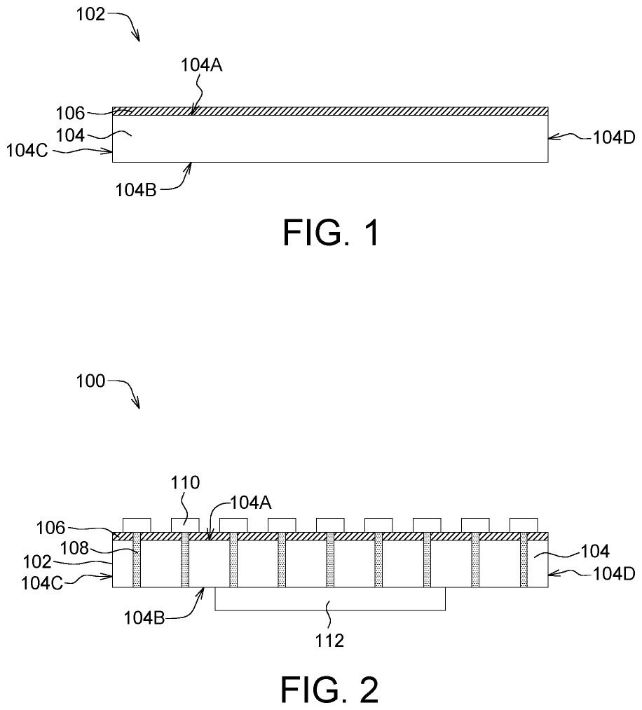

FIG. 1 to FIG. 3 illustrate a method for manufacturing a display apparatus according to an embodiment.

Referring to FIG. 1, a substrate structure 102 is provided. The substrate structure 102 comprises a transparent substrate 104 and an opaque film 106. The transparent substrate 104 comprises a first transparent surface 104A and a second transparent surface 104B opposing to the first transparent surface 104A, and a transparent sidewall surface 104C and a transparent sidewall surface 104D between the first transparent surface 104A and the second transparent surface 104B. The opaque film 106 covers on the first transparent surface 104A. In an embodiment, a material of the transparent substrate 104 comprises a transparent glass, such as a deep color transparent glass. The opaque film 106 may be formed on the transparent substrate 104 by a coating method or other suitable methods. A material of the opaque film 106 comprises a deep color glass, a dark color glass or a black color glass.

Referring to FIG. 2, a conductive element 108 passes through the transparent substrate 104 and the opaque film 106 of the substrate structure 102. A material of the conductive element 108 may comprise a metal such as copper and so on, but is not limited thereto. A light emitting unit 110 is disposed on the opaque film 106 over the first transparent surface 104A of the substrate structure 102, and is electrically connected to the conductive element 108. In an embodiment, the light emitting unit 110 comprises a micro-light emitting diode. The micro-light emitting diode may have a diagonal length within a range of 1 μm to 100 μm. An integrated circuit 112 is disposed on the second transparent surface 104B of the substrate structure 102. The light emitting unit 110 may be electrically connected to the integrated circuit 112 through the conductive element 108. The integrated circuit 112 may comprise a driving circuit used for controlling the light emitting unit 110, and so on. In an embodiment, the integrated circuit 112 may be electrically connected to the conductive element 108 through a conductive routing line (not shown) formed on the second transparent surface 104B. In an embodiment, the light emitting unit 110 may be electrically connected to the conductive element 108 by a conductive routing line (not shown) formed on the first transparent surface 104A. The light emitting unit 110 is not limited to arrange as being aligning or overlapping with the conductive element 108 as shown in FIG. 2. The light emitting unit 110 may be arranged to be miss-aligning or non-overlapping with the conductive element 108, and may be electrically connected to the conductive element 108 by the conductive routing line (not shown). In an embodiment, one of the light emitting units 110 may be electrically connected to another of the light emitting units 110 by using a bonding method. As such, a first display device 100 can be formed. The first display device 100 can be also singly used as a display apparatus. In practical application, a plurality of the light emitting units 110 is included, and correspondingly, a plurality of the conductive elements 108 is included, but the present disclosure is not limited thereto. In other embodiments, the opaque film 106 may cover on the second transparent surface 104B, but not cover on the first transparent surface 104A, while the integrated circuit 112 is disposed on the opaque film 106 on the second transparent surface 104B of the substrate structure 102. In other words, the opaque film 106 is between the second transparent surface 104B and the integrated circuit 112. Alternatively, the opaque film 106 may cover on both of the first transparent surface 104A and the second transparent surface 104B.

The opaque film 106 can shield other elements on a non-light emitting side of the light emitting unit 110, such as the conductive element 108, the integrated circuit 112, the conductive routing line, and so on, so as to avoid visual interference resulted from observing these elements by a user. The opaque film 106 can also be used to block a noise light on the non-light emitting side of the light emitting unit 110. Therefore, the first display device 100 and the display apparatus using the first display device 100 can have better display effect and provide better visual impression to a user.

Referring to FIG. 3, a second display device 200 is provided. Differences between the second display device 200 in this embodiment and the first display device 100 are described as the following. The second display device 200 comprises a substrate structure 202 comprising an opaque film 206 covering on a second transparent surface 204B of a transparent substrate 204. A light emitting unit 210 is disposed on a first transparent surface 204A of the transparent substrate 204. An integrated circuit 212 is disposed on the opaque film 206 over the second transparent surface 204B of the substrate structure 202. The light emitting unit 210 may be electrically connected to the integrated circuit 212 through the conductive element 208. In other embodiments, the opaque film 206 of the substrate structure 202 of the second display device 200 may further cover on the first transparent surface 204A, but not cover on the second transparent surface 204B. Alternatively, the opaque film 206 may cover on both of the first transparent surface 204A and the second transparent surface 204B.

Next, the first display device 100 and the second display device 200 are jointed together with the transparent sidewall surface 104D of the first display device 100 facing a transparent sidewall surface 204C of the second display device 200. In other words, the transparent sidewall surface 104D of the first display device 100 and the transparent sidewall surface 204C of the second display device 200 are juxtaposed and attached with each other. By which, jointing the first display device 100 and the second display device 200 is realized. However, the present disclosure is not limited thereto. Jointing the first display device 100 and the second display device 200 may be realized by attaching the transparent sidewall surface 104C with a transparent sidewall surface 204D. Alternatively, jointing the first display device 100 and the second display device 200 may be realized by attaching the transparent sidewall surface 104C with the transparent sidewall surface 204C. Otherwise, jointing the first display device 100 and the second display device 200 may be realized by attaching the transparent sidewall surface 104D with the transparent sidewall surface 204D.

In embodiments, the display devices of more quantity may be jointed together. The display apparatus is not limited to the structure as shown in FIG. 3, and can be adjusted properly according to the concept of the present disclosure. Some variations of the substrate structures used for the display device for the display apparatus are described below as examples.

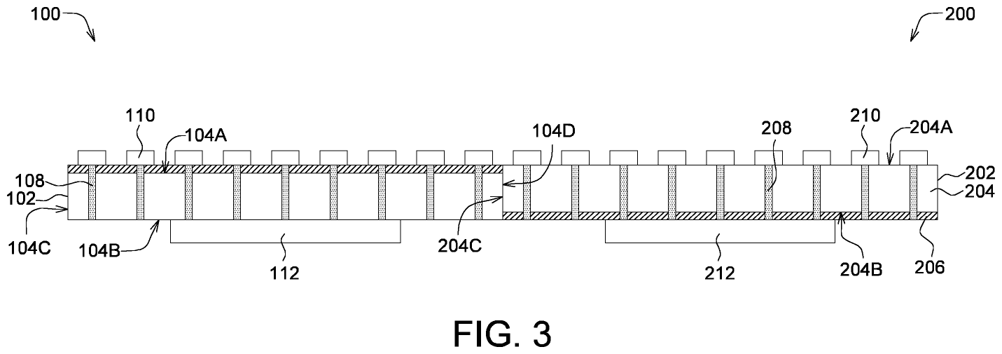

FIG. 4 illustrates a substrate structure 302 used for the display device according to another embodiment, which is different from the embodiment mentioned above (such as the substrate structure 102 as shown in FIG. 1) in that an opaque film 306 further covers on the transparent sidewall surface 104C and the transparent sidewall surface 104D of the transparent substrate 104. The opaque film 306 can further shield the transparent sidewall surface 104C and the transparent sidewall surface 104D from the external other elements or noise light that would affect the visual impression so as to improve display effect and improve visual impression to a user. Other variations can be understood. For example, the opaque film 306 may be also disposed on the second transparent surface 104B, and the opaque film 306 may be not disposed on the first transparent surface 104A. Otherwise, the opaque film 306 may be disposed on all of the first transparent surface 104A, the second transparent surface 104B, and the transparent sidewall surface 104C and the transparent sidewall surface 104D.

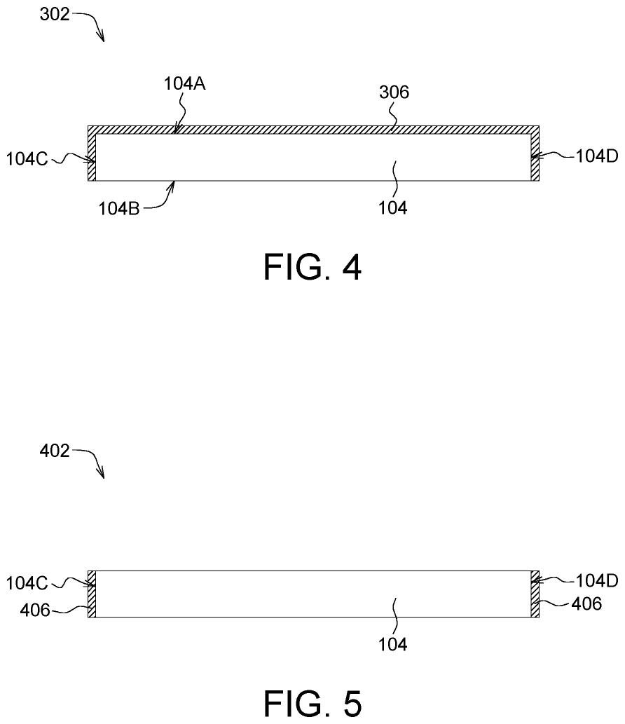

FIG. 5 is referred to, which illustrates a substrate structure 402 used for the display device according to yet another embodiment. In this embodiment, an opaque film 406 covers on the transparent sidewall surface 104C and the transparent sidewall surface 104D of the transparent substrate 104.

Accordingly, the present invention discloses a display apparatus comprising a transparent substrate, light emitting units, and an opaque film. The transparent substrate comprises a first transparent surface and a second transparent surface opposing to each other. The light emitting units are disposed over the first transparent surface. The opaque film covers on at least one of the first transparent surface and the second transparent surface to shield internal electronic elements so as to avoid visual interference resulted from observing these elements by a user. Therefore, the display apparatus has better display effect, and provides better visual impression to a user.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A display apparatus, comprising:
a transparent substrate comprising a first transparent surface and a second transparent surface opposing to the first transparent surface;
light emitting units disposed over the first transparent surface; and
an opaque film covering on at least one of the first transparent surface and the second transparent surface.

2. The display apparatus according to claim 1, wherein when the opaque film covers on the first transparent surface, the display apparatus further comprises:
conductive elements passing through the transparent substrate; and
an integrated circuit disposed on the second transparent surface, wherein the light emitting units are electrically connected to the integrated circuit through the conductive elements.

3. The display apparatus according to claim 1, wherein when the opaque film covers on the second transparent surface, the display apparatus further comprises:
conductive elements passing through the transparent substrate and the opaque film; and
an integrated circuit disposed on the opaque film between the second transparent surface and the integrated circuit, wherein the light emitting units are electrically connected to the integrated circuit through the conductive elements.

4. The display apparatus according to claim 1, wherein the transparent substrate further comprises a transparent sidewall surface between the first transparent surface and the second transparent surface, the opaque film covers on the transparent sidewall surface.

5. The display apparatus according to claim 1, wherein a material of the transparent substrate comprises a transparent glass.

6. The display apparatus according to claim 1, wherein a material of the opaque film comprises a deep color glass, a dark color glass, or a black color glass.

7. The display apparatus according to claim 1, wherein the light emitting units comprise micro-light emitting diodes.

8. The display apparatus according to claim 1, further comprising conductive elements passing through the transparent substrate and the opaque film, and electrically connected to the light emitting units.

9. The display apparatus according to claim 1, comprising a first display device comprising the transparent substrate, the light emitting units and the opaque film, wherein the display apparatus further comprises a second display device, the second display device comprises:
another transparent substrate comprising another first transparent surface and another second transparent surface opposing to the another first transparent surface;
another light emitting units disposed over the another first transparent surface; and
another opaque film covering on at least one of the another first transparent surface and the another second transparent surface,
wherein the first display device and the second display device are jointed together.

10. The display apparatus according to claim 9, wherein the another transparent substrate further comprises another transparent sidewall surface between the another first transparent surface and the another second transparent surface, the another opaque film covers on the another transparent sidewall surface.

11. The display apparatus according to claim 9, wherein the first display device comprises opposing two transparent sidewall surfaces, the second display device comprises opposing two another transparent sidewall surfaces, jointing the first display device and the second display device is realized by attaching one sidewall surface of the two transparent sidewall surfaces of the first display device with one sidewall surface of the two another transparent sidewall surfaces of the second display device.

12. The display apparatus according to claim 9, wherein the opaque film covers on the first transparent surface of the first display device, the first display device further comprises:
conductive elements passing through the transparent substrate; and
an integrated circuit disposed on the second transparent surface, wherein the light emitting units are electrically connected to the integrated circuit through the conductive elements.

13. The display apparatus apparatus according to claim 9, wherein the opaque film covers on the second transparent surface of the first display device, the first display device further comprises:
conductive elements passing through the transparent substrate and the opaque film; and
an integrated circuit disposed on the opaque film between the second transparent surface and the integrated circuit, wherein the light emitting units are electrically connected to the integrated circuit through the conductive elements.

14. The display apparatus according to claim 9, wherein the transparent substrate of the first display device further comprises a transparent sidewall surface between the first transparent surface and the second transparent surface, the opaque film covers on the transparent sidewall surface.

15. The display apparatus according to claim 9, wherein a material of the transparent substrate of the first display device comprises a transparent glass.

16. The display apparatus according to claim 9, wherein a material of the opaque film of the first display device comprises a deep color glass, a dark color glass, or a black color glass.

17. The display apparatus according to claim 9, wherein the light emitting units of the first display device comprise micro-light emitting diodes.

18. The display apparatus according to claim 9, wherein the first display device further comprises conductive elements passing through the transparent substrate and the opaque film, and electrically connected to the light emitting units.

19. The display apparatus according to claim 9, wherein a material of the another opaque film of the second display device comprises a deep color glass, a dark color glass, or a black color glass.

20. The display apparatus according to claim 9, wherein a structure of the first display device is identical to or different from a structure of the second display device.
